(19) United States
(12) Patent Application Publication
(10) Pub. No.: US 2025/0331425 A1
(43) Pub. Date: Oct. 23, 2025

(54) LAMINATED PIEZOELECTRIC ELEMENT AND ELECTROACOUSTIC TRANSDUCER

(71) Applicant: FUJIFILM Corporation, Tokyo (JP)

(72) Inventor: Yoshinori TAMADA, Minamiashigara-shi (JP)

(73) Assignee: FUJIFILM Corporation, Tokyo (JP)

(21) Appl. No.: 19/256,547

(22) Filed: Jul. 1, 2025

Related U.S. Application Data
(63) Continuation of application No. PCT/JP2024/001097, filed on Jan. 17, 2024.

(30) Foreign Application Priority Data
Feb. 28, 2023 (JP) 2023-029852

(51) Int. Cl. H10N 30/50; H04R 17/02; H10N 30/00; H10N 30/20; H10N 30/85; H10N 30/857; H10N 30/87

(52) U.S. Cl. CPC H10N 30/50; H04R 17/025; H10N 30/206; H10N 30/708; H10N 30/852; H10N 30/857; H10N 30/871; H10N 30/872

(57) ABSTRACT

Provided are a laminated piezoelectric element and an electroacoustic transducer, in which a high sound pressure can be obtained even after long-term use of a laminated piezoelectric element obtained by laminating a piezoelectric film in a plurality of layers. In the laminated piezoelectric element, in which a plurality of piezoelectric films are laminated with adhesive layers interposed between the plurality of piezoelectric films, the adhesive layer has an adhesive region and a gap portion, in a case where a cross section of the piezoelectric films of the laminated piezoelectric element in a lamination direction is observed with a scanning electron microscope in each of one in-plane direction of a main surface of the piezoelectric films, a direction orthogonal to the one direction, a direction inclined by 45° with respect to the one direction, and a direction inclined by 135° with respect to the one direction to acquire ten continuous visual fields, and an average value of thicknesses of the piezoelectric films observed in each visual field is denoted by d₁ and an average value of thicknesses of the adhesive layers observed in each visual field is denoted by d₂, a ratio d₂/d₁ is 0.15 or more and 1.0 or less, and a ratio of a total area of the gap portions to a total area of the adhesive layers observed in each visual field is 1% or more and less than 40%.

### CROSS-REFERENCE TO RELATED APPLICATIONS

This application is a Continuation of PCT International Application No. PCT/JP2024/001097 filed on Jan. 17, 2024, which claims priority under 35 U.S.C. § 119(a) to Japanese Patent Application No. 2023-029852 filed on Feb. 28, 2023. The above applications are hereby expressly incorporated by reference, in their entirety, into the present application.

### BACKGROUND OF THE INVENTION

### 1. Field of the Invention

The present invention relates to a laminated piezoelectric element and an electroacoustic transducer.

### 2. Description of the Related Art

A piezoelectric element, so-called exciter, which is brought into contact and attached to various articles and vibrates the articles to generate a sound, has been used for various applications. For example, instead of a speaker, a sound can be generated by attaching the exciter to an image display panel, a screen, or the like, and vibrating them.

As the piezoelectric element, it has been proposed to use a piezoelectric film in which a piezoelectric layer is sandwiched between an electrode layer and a protective layer. In addition, it has been also proposed to laminate the piezoelectric film in a plurality of layers through an adhesive layer, and to use the laminate as a laminated piezoelectric element.

For example, WO2020/196850A discloses a piezoelectric film including a polymer-based piezoelectric composite material in which piezoelectric particles are dispersed in a matrix containing a polymer material, and electrode layers formed on both surfaces of the polymer-based piezoelectric composite material, in which a loss tangent at a frequency of 1 kHz according to a dynamic viscoelasticity measurement has a maximal value of 0.1 or more in a temperature range of higher than 50° C. and 150° C. or lower, and has a value of 0.08 or more at 50° C. In addition, WO2020/196850A discloses a piezoelectric element in which the piezoelectric film is laminated in a plurality of layers by folding the piezoelectric film one or more times.

### SUMMARY OF THE INVENTION

The laminated piezoelectric element obtained by laminating the piezoelectric film in a plurality of layers is used as an exciter which generates a sound from a vibration plate by being attached to the vibration plate and vibrating the vibration plate. In an electroacoustic transducer formed by attaching the laminated piezoelectric element to the vibration plate, it is desired to obtain a high sound pressure even after long-term use. Therefore, a high initial sound pressure is required.

In addition, it is found that there is a problem in that, even in the case where the initial sound pressure is high, the sound pressure decreases with time due to long-term use.

Regarding the point, as a result of studies conducted by the present inventors, in a case where power is applied to the laminated piezoelectric element to generate the sound, the laminated piezoelectric element repeatedly stretches and contracts. Since the laminated piezoelectric element is attached to the vibration plate, the laminated piezoelectric element undergoes repeated significant warping. In this case, it is found that a difference in amount of stretch and contraction occurs in a thickness direction of the laminated piezoelectric element, and thus defects such as peeling at an interface between the piezoelectric film and an adhesive layer occur due to application of stress.

An object of the present invention is to solve the problems of the related art, and to provide a laminated piezoelectric element and an electroacoustic transducer, in which a high sound pressure can be obtained even after long-term use of a laminated piezoelectric element obtained by laminating a piezoelectric film in a plurality of layers.

In order to solve the above-described problems, the present invention has the following configuration.
[1] A laminated piezoelectric element in which a plurality of piezoelectric films are laminated with adhesive layers interposed between the plurality of piezoelectric films,
in which the adhesive layer has an adhesive region and a gap portion in an in-plane direction of a main surface of the piezoelectric films,
in a case where a cross section of the piezoelectric films of the laminated piezoelectric element in a lamination direction is observed with a scanning electron microscope in each of one in-plane direction of the main surface of the piezoelectric films, a direction orthogonal to the one direction, a direction inclined by 45° with respect to the one direction, and a direction inclined by 135° with respect to the one direction to acquire ten continuous visual fields, and an average value of thicknesses of the piezoelectric films observed in each visual field is denoted by d₁ and an average value of thicknesses of the adhesive layers observed in each visual field is denoted by d₂, a ratio d₂/d₁ is 0.15 or more and 1.0 or less, and
a ratio of a total area of the gap portions to a total area of the adhesive layers observed in each visual field is 1% or more and 40% or less.
[2] The laminated piezoelectric element according to [1],
in which the piezoelectric film includes a piezoelectric layer consisting of a polymer-based piezoelectric composite material containing piezoelectric particles in a matrix containing a polymer material, and electrode layers provided on both surfaces of the piezoelectric layer.
[3] The laminated piezoelectric element according to [1],
in which the piezoelectric film is laminated in a plurality of layers by folding the piezoelectric film one or more times.
[4] An electroacoustic transducer obtained by attaching the laminated piezoelectric element according to any one of [1] to [3] to a vibration plate.

According to the present invention, it is possible to provide a laminated piezoelectric element and an electroacoustic transducer, in which a high sound pressure can be obtained even after long-term use of a laminated piezoelectric element obtained by laminating a piezoelectric film in a plurality of layers.

### BRIEF DESCRIPTION OF THE DRAWINGS

FIG. 1 is a perspective view conceptually showing an example of the laminated piezoelectric element according to the embodiment of the present invention.

FIG. 2 is a view conceptually showing an example of an electroacoustic transducer including the laminated piezoelectric element shown in FIG. 1.

FIG. 3 is a partially enlarged view of FIG. 2.

FIG. 4 is a plan view conceptually showing an adhesive layer included in the laminated piezoelectric element shown in FIG. 1.

FIG. 5 is a cross-sectional view of the electroacoustic transducer shown in FIG. 2.

FIG. 6 is a view for describing an action of the laminated piezoelectric element according to the embodiment of the present invention.

FIG. 7 is a plan view conceptually showing another example of the adhesive layer included in the laminated piezoelectric element according to the embodiment of the present invention.

FIG. 8 is a plan view conceptually showing another example of the adhesive layer included in the laminated piezoelectric element according to the embodiment of the present invention.

FIG. 9 is a plan view conceptually showing another example of the adhesive layer included in the laminated piezoelectric element according to the embodiment of the present invention.

FIG. 10 is a partially enlarged view conceptually showing another example of the laminated piezoelectric element according to the embodiment of the present invention.

FIG. 11 is a view schematically showing an example of a piezoelectric film included in the laminated piezoelectric element according to the embodiment of the present invention.

FIG. 12 is a conceptual view for describing an example of a production method of the piezoelectric film.

FIG. 13 is a conceptual view for describing an example of a production method of the piezoelectric film.

FIG. 14 is a conceptual view for describing an example of a production method of the piezoelectric film.

FIG. 15 is a conceptual view for describing an example of an electroacoustic transducer including a laminated piezoelectric element in the related art.

### DESCRIPTION OF THE PREFERRED EMBODIMENTS

Hereinafter, the laminated piezoelectric element and electroacoustic transducer according to the embodiments of the present invention will be described in detail based on suitable examples shown in the accompanying drawings.

Although configuration requirements to be described below are described based on representative embodiments of the present invention, the present invention is not limited to the embodiments.

Any numerical range expressed using “to” in the present specification refers to a range including the numerical values before and after the “to” as a lower limit value and an upper limit value, respectively.

### [Laminated Piezoelectric Element and Electroacoustic Transducer]

The laminated piezoelectric element according to the embodiment of the present invention is a laminated piezoelectric element in which a plurality of piezoelectric films are laminated with adhesive layers interposed between the plurality of piezoelectric films, the adhesive layer has an adhesive region and a gap portion in an in-plane direction of a main surface of the piezoelectric films, in a case where a cross section of the piezoelectric films of the laminated piezoelectric element in a lamination direction is observed with a scanning electron microscope in each of one in-plane direction of the main surface of the piezoelectric films, a direction orthogonal to the one direction, a direction inclined by 45° with respect to the one direction, and a direction inclined by 135° with respect to the one direction to acquire ten continuous visual fields, and an average value of thicknesses of the piezoelectric films observed in each visual field is denoted by d₁ and an average value of thicknesses of the adhesive layers observed in each visual field is denoted by d₂, a ratio d₂/d₁ is 0.15 or more and 1.0 or less, and a ratio of a total area of the gap portions to a total area of the adhesive layers observed in each visual field is 1% or more and 40% or less.

The electroacoustic transducer according to the embodiment of the present invention is an electroacoustic transducer obtained by attaching the above-described laminated piezoelectric element to a vibration plate.

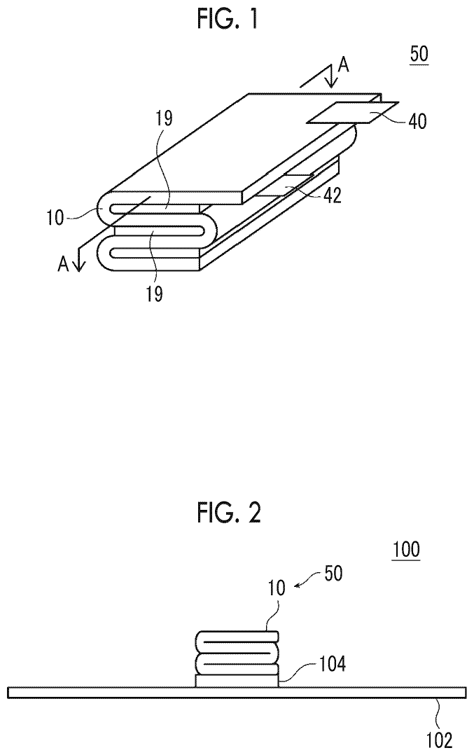

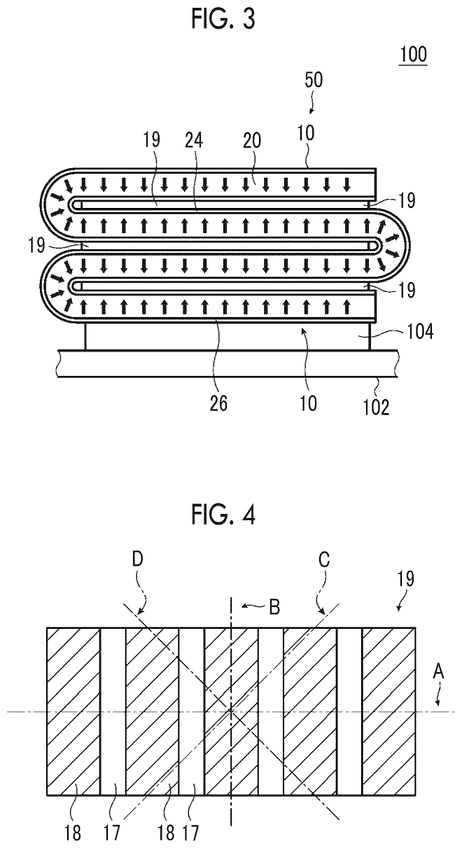

FIG. 1 shows a perspective view conceptually representing an example of the laminated piezoelectric element according to the embodiment of the present invention. FIG. 2 shows a view schematically representing an example of the electroacoustic transducer according to the embodiment of the present invention, including the laminated piezoelectric element shown in FIG. 1. In addition, FIG. 3 shows a partially enlarged view of FIG. 2.

A laminated piezoelectric element 50 shown in FIGS. 1 to 3 is formed by laminating a piezoelectric film 10 in four layers by folding one rectangular sheet of the piezoelectric film 10 three times in one direction. That is, the laminated piezoelectric element 50 is a laminated piezoelectric element in which the piezoelectric films 10 are laminated in four layers.

In FIGS. 1 to 3, the drawing is simplified to clearly show the configuration of the laminated piezoelectric element 50, but the piezoelectric film 10 includes electrode layers on both surfaces of a piezoelectric layer 20 and includes a protective layer which covers the electrode layers.

In addition, in the following description, a direction in which the piezoelectric film 10 is folded (a left-right direction in FIG. 1) will be referred to as a folding-back direction.

Although described in detail later, for example, the piezoelectric film 10 includes a piezoelectric layer having piezoelectricity, electrode layers provided on both surfaces of the piezoelectric layer, and protective layers provided on the electrode layers. In a case where a voltage is applied to the electrode layers (electrode pair) which sandwich the piezoelectric layer, the piezoelectric layer stretches and contracts according to the applied voltage. As a result, the piezoelectric film 10 (piezoelectric layer 20) contracts in the thickness direction. At the same time, the piezoelectric film 10 stretches and contracts in the plane direction due to the Poisson's ratio. In this manner, the piezoelectric film 10 can exhibit piezoelectric characteristics.

By folding the piezoelectric film 10 having such piezoelectric characteristics, the laminated piezoelectric element 50 can be obtained by laminating the piezoelectric film in a plurality of layers.

In the example shown in FIG. 1, the laminated piezoelectric element 50 has a laminated portion in which four layers of the piezoelectric film 10 overlap each other in a plan view, and a protruding portion which protrudes outward from the laminated portion in the plane direction.

In the present invention, the laminated portion is a region where two or more layers of the piezoelectric film overlap each other in a plan view, that is, in a case where the laminated piezoelectric element is viewed from above (or below) in FIG. 1. That is, in the examples shown in FIGS. 1 and 2, a region where four layers of the piezoelectric film 10 overlap each other is the laminated portion. In the example shown in FIG. 1, the laminated portion has a substantially rectangular shape, in which a short side extends in a folding-back direction and a long side extends in a direction orthogonal to the folding-back direction.

On the other hand, the protruding portion is a region where protrudes from the laminated portion in the plane direction, and is a region where does not overlap with other layers in a plan view. In the drawing of the example shown in FIG. 1, a right end part of the uppermost layer is the protruding portion. In the examples shown in FIGS. 2 and 3, the protruding portion is not shown.

In the laminated portion, layers of the adjacent piezoelectric films 10 are adhered to each other by an adhesive layer 19. In the present invention, the adhesive layer 19 has an adhesive region for adhering layers to each other and a gap portion. The adhesive layer 19 will be described in detail later.

As shown in FIG. 1, a conductive wire 40 and a conductive wire 42, for connecting the two electrode layers to an external power supply, are formed on the protruding portion. In a case where the piezoelectric film 10 includes the protective layer, a through-hole is formed in the protective layers in the region of the protruding portion to expose the electrode layers, and a connecting portion is provided so that the conductive wire 40 and the conductive wire 42 are electrically connected to the electrode layers. A method of forming the through-hole is not particularly limited, and a known method such as laser processing, dissolution removal using a solvent, or mechanical processing such as mechanical polishing may be performed according to a forming material of the protective layer.

A conductive wire filled with a known conductive material such as a conductive metal paste, for example, a silver paste, a conductive carbon paste, and a conductive nano ink is connected to the connecting portion and is connected to an external power supply.

A method of connecting the electrode layer and the conductive wire in the protruding portion is not limited, and various known methods can be used.

Examples thereof include a method of connecting a conductor such as a copper foil to the electrode layer and leading-out the electrode to the outside, and a method of forming through-holes in the protective layer with a laser or the like, filling the through-holes with a conductive material, and leading-out the electrode to the outside.

In addition, in the example shown in FIG. 1, the protruding portion is provided and the electrode layers are connected to the external power supply by the protruding portion, but the present invention is not limited thereto, and the electrode layers and the conductive wires may be electrically connected to each other in the laminated portion.

Examples of a suitable method of leading out the electrodes include the method described in JP2014-209724A and the method described in JP2016-015354A.

As shown in FIG. 2, the laminated piezoelectric element 50 according to the embodiment of the present invention is attached to a vibration plate 102 through a bonding layer 104 to constitute an electroacoustic transducer 100.

In such an electroacoustic transducer 100, the laminated piezoelectric element 50 is driven by applying a voltage to the electrode layers of the laminated piezoelectric element 50 using an external power supply. In a case where the laminated piezoelectric element 50 is driven, the laminated piezoelectric element 50 stretches and contracts in the plane direction, and the laminated piezoelectric element 50 bends the vibration plate 102 to which the laminated piezoelectric element 50 is bonded, and as a result, the vibration plate 102 is vibrated to generate a sound. The vibration plate 102 is vibrated according to a magnitude of a driving voltage applied to the laminated piezoelectric element 50, and generates the sound according to the driving voltage applied to the laminated piezoelectric element 50.

That is, the laminated piezoelectric element 50 can be used as an exciter.

Here, in the laminated piezoelectric element 50 according to the embodiment of the present invention, the adhesive layer 19 has the gap portion and the adhesive region in the in-plane direction of the main surface, and in a case where a cross section of the adhesive layer 19 is observed with a scanning electron microscope (SEM), an area ratio of the gap portion in the adhesive layer 19 and a thickness ratio of the piezoelectric film and the adhesive layer are set to predetermined ranges, respectively.

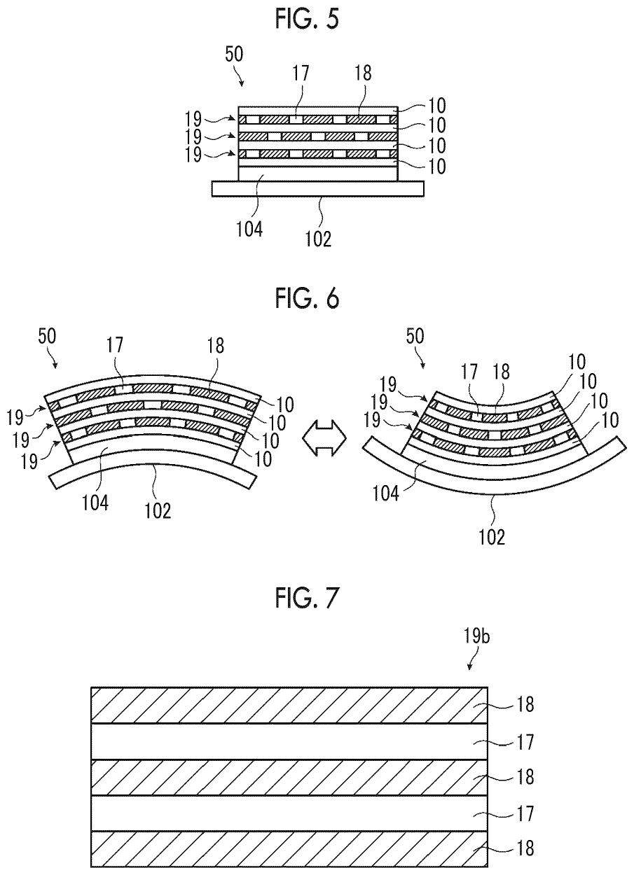

This point will be described with reference to FIGS. 4 and 5.

FIG. 4 is a plan view conceptually showing the adhesive layer 19 included in the laminated piezoelectric element 50 shown in FIG. 1. FIG. 5 is a cross-sectional view taken along a line A-A of the laminated piezoelectric element 50 shown in FIG. 1. The plan view is a view of the laminated piezoelectric element in a lamination direction in which the piezoelectric film 10 is laminated in a plurality of layers.

As shown in FIG. 4, the adhesive layer 19 has a configuration in which an adhesive region 18 and a gap portion 17 are alternately arranged, that is, in a stripe shape in the long side direction (a left-right direction in FIG. 4).

In a case where a cross section of the laminated piezoelectric element 50 having the configuration in which each adhesive layer 19 has the adhesive region 18 and the gap portion 17 in a stripe shape is observed with an SEM in the lamination direction (that is, the thickness direction) of the piezoelectric film 10, the adhesive region 18 and the gap portion 17 in the adhesive layer 19 are observed as shown in FIG. 5.

In the present invention, in a case where each cross section is observed with SEM in each of one in-plane direction of the main surface of the piezoelectric film, a direction orthogonal to the one direction, a direction inclined by 45° with respect to the one direction, and a direction inclined by 135° with respect to the one direction to acquire ten continuous visual fields, and an average value of thicknesses of the piezoelectric film 10 observed in each visual field is denoted by d₁ and an average value of thicknesses of the adhesive layer observed in each visual field is denoted by d₂, the ratio d₂/d₁ is 0.15 or more and 0.1 or less, and the ratio of the total area of the gap portions to the total area of the adhesive layers observed in each visual field is 1% or more and 40% or less.

For example, through a center of the rectangular laminated portion, a cross section is taken in each of a direction parallel to the long side (one-dot chain line A in FIG. 4), a direction parallel to the short side (one-dot chain line B in FIG. 4), a direction inclined by 45° with respect to the long side (one-dot chain line C in FIG. 4), and a direction inclined by 135° with respect to the long side (one-dot chain line D in FIG. 4; a direction orthogonal to the direction inclined by 45°), and observed with SEM to acquire ten continuous visual fields. In this case, in the cross section in the direction of the one-dot chain line A, as shown in FIG. 5, the adhesive region 18 and the gap portion 17 of each adhesive layer 19 are observed. On the other hand, in the cross section in the direction of the one-dot chain line B, the entire region of the adhesive layer 19 is observed as the adhesive region 18. In addition, in the cross section in the direction of the one-dot chain line C and the cross section in the direction of the one-dot chain line D, the adhesive region 18 and the gap portion 17 of each adhesive layer 19 are observed.

In the above-described example, the cross sections are taken in four directions such that one direction is a direction parallel to the long side of the rectangular laminated portion, but the present invention is not limited thereto. The cross sections in the four directions may be cross sections in directions perpendicular to each other and directions of 45° and 135°, and any of the directions may not be parallel to the long side and the short side.

In addition, in the above-described example, any cross section passes through the center of the rectangular laminated portion; but the present invention is not limited thereto, and the cross section may be acquired at any position.

For example, the observation of the cross section may be specifically performed as follows.

In order to observe the cross section of the laminated piezoelectric element, the laminated piezoelectric element is cut in the thickness direction. For example, it is sufficient that the laminated piezoelectric element is cut by mounting a histo knife blade manufactured by Drukker, having a width of 8 mm, equipped on RM2265 manufactured by Leica Biosystems, and setting a speed to a controller scale of 1 and an engagement amount of 0.25 μm to 1 μm.

The cross section thereof is observed with an SEM (for example, SU8220, manufactured by Hitachi High-Technologies Corporation).

An example of conditions for observation with the SEM is shown below.

The sample is subjected to a conductive treatment by platinum vapor deposition, and the work distance is set to 8 mm.

The observation is performed under conditions of a secondary-electron (SE) image (Upper) and an acceleration voltage of 0.5 kV, the sharpest image is output by focus adjustment and astigmatism adjustment, and automatic brightness adjustment (auto setting, brightness: 0, contrast: 0) is performed in a state in which the piezoelectric film covers the entire screen.

The imaging magnification is set such that the thickness direction of the laminated piezoelectric element is within one screen and the thickness direction of the laminated piezoelectric element is equal to or more than half of the screen. In addition, in this case, the imaging is performed such that the piezoelectric film in the lowermost layer is horizontal to the lower part of the image.

Ten continuous visual fields of the cross section of the laminated piezoelectric element are imaged with the SEM at any position. As described above, the SEM observation is performed in four directions. In this manner, a total of 40 SEM images of the visual fields are acquired.

The total area of the adhesive layers 19 and the total area of the gap portions 17 in the adhesive layer 19 in the total of the obtained 40 SEM images of the visual fields are obtained, and a ratio of the total area of the gap portions 17 to the total area of the adhesive layers 19 is calculated.

A method of obtaining the total area of the adhesive layers 19 and the total area of the gap portions 17 in the adhesive layer 19 from the SEM images is not particularly limited, and the total area may be obtained using commercially available image processing software such as WinROOF.

For each visual field of the obtained SEM images, the thickness of each piezoelectric film 10 and the thickness of each adhesive layer 19 (adhesive region 18) are measured at intervals of 1 μm at 10 points or more, and an average value thereof is obtained. The average value d₁ of the thicknesses of the piezoelectric films 10 measured in all visual fields and the average value d₂ of the thicknesses of the adhesive layers 19 in all visual fields are calculated, and the ratio d₂/d₁ is calculated.

In the present invention, the ratio of the total area of the gap portions 17 to the total area of the adhesive layers 19, which are measured as described above, is 1% or more and 40% or less.

In addition, the ratio d₂/d₁ of the thickness (average value) of the piezoelectric film 10 to the thickness (average value) of the adhesive layer 19 is 0.15 or more and 1.0 or less.

As described above, in the electroacoustic transducer obtained by attaching the laminated piezoelectric element to the vibration plate, in order to obtain a high sound pressure even after long-term use, it is necessary to increase an initial sound pressure and to suppress a decrease in sound pressure over time.

As a result of the studies conducted by the present inventors, it is found that the cause of the decrease in sound pressure over time is due to the following mechanism.

In a case where the laminated piezoelectric element obtained by laminating a piezoelectric film in a plurality of layers is attached to the vibration plate and used as an exciter, the laminated piezoelectric element repeatedly stretches and contracts as power is applied to the laminated piezoelectric element to generate a sound. However, since the laminated piezoelectric element is attached to the vibration plate, the laminated piezoelectric element undergoes repeated significant warping.

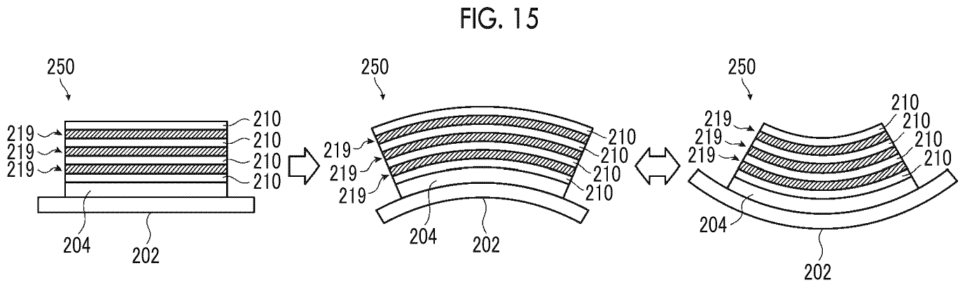

As in the laminated piezoelectric element 250 of the related art in the left diagram of FIG. 15, in a case where the entire surface of the piezoelectric film 10 is attached by the adhesive layer 219, as shown in the middle and right diagrams of FIG. 15, when the laminated piezoelectric element 250 is warped, a difference in amount of stretch and contraction occurs in the thickness direction of the laminated piezoelectric element 250, so that there is a problem that defects such as peeling at an interface between the piezoelectric film 210 and the adhesive layer 219 occur due to the application of stress. As a result, it is found that there is a problem that the sound pressure decreases over time with the long-term use.

On the other hand, in the laminated piezoelectric element 50 according to the embodiment of the present invention, the adhesive layer 19 has the adhesive region 18 and the gap portion 17, and the ratio of the total area of the gap portions 17 to the total area of the adhesive layers 19 in the cross section observed with the SEM is 1% or more and 40% or less.

Since the laminated piezoelectric element 50 has the gap portion 17 in the range, the application of stress in a case where the laminated piezoelectric element 50 is repeatedly warped can be relaxed during the application of power to the laminated piezoelectric element 50 to generate a sound, and the occurrence of peeling at the interface between the piezoelectric film 10 and the adhesive layer 19 can be suppressed (see FIG. 6). As a result, it is possible to suppress the decrease in sound pressure over time even in a case of long-term use.

On the other hand, in a case where the area ratio of the gap portion 17 is excessively high (more than 40%), the stretch and contraction (vibration) of the piezoelectric film 10 is less likely to be transmitted to the vibration plate 102, and thus there is a concern that the initial sound pressure may decrease. On the other hand, by setting the area ratio of the gap portion 17 to 40% or less, the stretch and contraction (vibration) of the piezoelectric film 10 is transmitted to the vibration plate 102, and thus the initial sound pressure can be maintained at a high level. Therefore, the electroacoustic transducer using the laminated piezoelectric element 50 according to the embodiment of the present invention can obtain a high sound pressure even after long-term use.

In addition, in the laminated piezoelectric element 50 according to the embodiment of the present invention, the ratio d₂/d₁ of the thickness d₂ of the adhesive layer 19 to the thickness d₁ of the piezoelectric film 10 is 0.15 or more and 1.0 or less. By setting the ratio d₂/d₁ to 0.15 or more, that is, by making the thickness of the adhesive layer 19 somewhat thick, an adhesive force between the piezoelectric film 10 and the adhesive layer 19 can be secured, and thus the occurrence of peeling at the interface between the piezoelectric film 10 and the adhesive layer 19 can be suppressed. In addition, by setting the ratio d₂/d₁ to 1.0 or less, that is, by not excessively increasing the thickness of the adhesive layer 19, the stretch and contraction of the piezoelectric film 10 can be suppressed from being absorbed by the adhesive layer 19, and can be transmitted to the vibration plate 102. As a result, the initial sound pressure can be increased, and the sound pressure after use can also be increased.

Here, from the viewpoint of suppressing the occurrence of peeling at the interface between the piezoelectric film 10 and the adhesive layer 19 and increasing the initial sound pressure, the ratio of the total area of the gap portions 17 to the total area of the adhesive layers 19 is preferably 2% or more and 35% or less, and more preferably 5% or more and 30% or less.

In addition, from the viewpoint of increasing the initial sound pressure and the sound pressure after use, the ratio d₂/d₁ of the thickness d₂ of the adhesive layer 19 to the thickness d₁ of the piezoelectric film 10 is preferably 0.2 or more and 0.75 or less, and more preferably 0.3 or more and 0.5 or less.

In addition, in the above-described example, the adhesive layer 19 has the configuration in which the adhesive region 18 and the gap portion 17 are alternately arranged, that is, in a stripe shape in the long side direction as shown in FIG. 4, but the arrangement pattern of the adhesive region 18 and the gap portion 17 is not limited to the configuration as long as the ratio of the total area of the gap portions 17 to the total area of the adhesive layers 19 satisfies the above-described range.

For example, as in an adhesive layer 19b shown in FIG. 7, a configuration in which the adhesive region 18 and the gap portion 17 are alternately arranged, that is, in a stripe shape in the short side direction may be adopted.

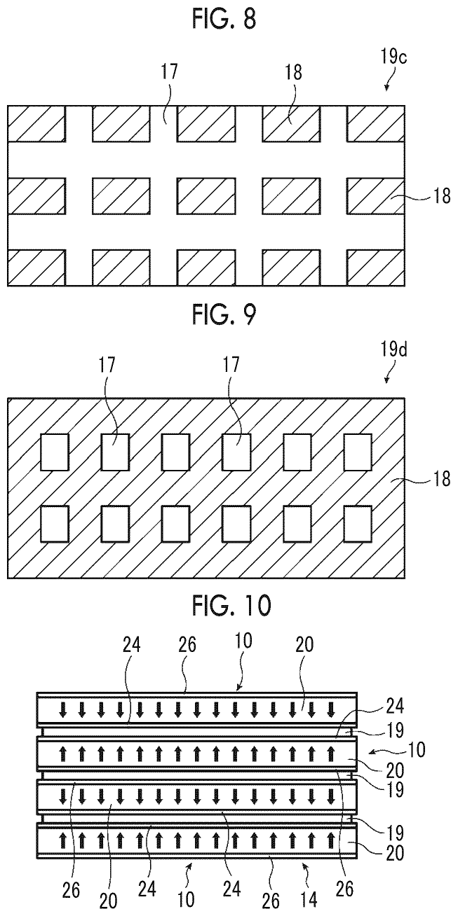

Alternatively, as in an adhesive layer 19c shown in FIG. 8, a lattice-like configuration in which the gap portions 17 parallel to each of the long side and the short side are arranged may be adopted.

Alternatively, as in an adhesive layer 19d shown in FIG. 9, a lattice-like configuration in which the adhesive regions 18 parallel to each of the long side and the short side are arranged may be adopted.

In addition, in a case of the configuration in which the adhesive region 18 and the gap portion 17 are arranged in a stripe shape as in the examples shown in FIGS. 4 and 7, a width of the adhesive region 18 (a width of the adhesive region 18 and the gap portion 17 in the arrangement direction) is preferably 1 μm to 5,000 μm, more preferably 5 μm to 2,500 μm, and still more preferably 10 μm to 1,000 μm.

The arrangement patterns of the adhesive region 18 and the gap portion 17 in the plurality of the adhesive layers 19 of the laminated piezoelectric element 50 may be the same or different from each other. For example, one adhesive layer 19 may have the configuration in which the adhesive region 18 and the gap portion 17 are arranged in a stripe shape in the long side direction as shown in FIG. 4, and the other adhesive layer 19 may have the configuration in which the adhesive region 18 and the gap portion 17 are arranged in a stripe shape in the short side direction as shown in FIG. 7.

In addition, the plurality of the adhesive layers 19 may be disposed in the same disposition pattern, and disposition positions of the adhesive region 18 and the gap portion 17 may be shifted from each other in a plane. That is, as in the uppermost adhesive layer 19 and the middle adhesive layer 19 of the laminated piezoelectric element 50 shown in FIG. 5, the position of the gap portion 17 may be shifted in the in-plane direction (a left-right direction in FIG. 5).

In the example shown in FIG. 1, the laminated piezoelectric element 50 is formed by folding the piezoelectric film 10 three times and laminating four layers of the piezoelectric film 10; but the present invention is not limited thereto, and the laminated piezoelectric element may be formed by laminating two or three layers of the piezoelectric films or may be formed by laminating five or more layers of the piezoelectric films. The same also applies to a piezoelectric element shown in FIG. 10, which will be described later.

In addition, in the example shown in FIG. 1, the laminated piezoelectric element 50 include the piezoelectric film in which a plurality of layers are laminated by folding the long piezoelectric film 10 once or more, but the present invention is not limited thereto. As shown in FIG. 10, the laminated piezoelectric element may have a configuration in which a plurality of sheet-like (cut sheet-like) piezoelectric films 10 are laminated.

In the laminated piezoelectric element shown in FIG. 10, four piezoelectric films 10 are laminated through adhesive layers 19. The four piezoelectric films 10 are connected to a power source (not shown).

In the laminated piezoelectric element shown in FIG. 10, as a preferred aspect, the piezoelectric film 10 is polarized in the thickness direction, and polarization directions of the adjacent piezoelectric films 10 are opposite to each other. Therefore, in the adjacent piezoelectric films 10, the first electrode layers 24 face each other and the second electrode layers 26 face each other. Therefore, the power supply constantly supplies power of the same polarity to the facing electrodes regardless of whether the power supply is an alternating-current power supply or a direct-current power supply. Accordingly, in the laminated piezoelectric element shown in FIG. 10, even in a case where the electrodes of the adjacent piezoelectric films 10 come into contact with each other, there is no risk of a short circuit.

The polarization direction of the piezoelectric film 10 may be detected by a d33 meter or the like. Alternatively, the polarization direction of the piezoelectric film 10 may be known from polarization treatment conditions described later.

In addition, in the example shown in FIG. 10, the polarization directions of the adjacent piezoelectric films 10 are opposite to each other; but the present invention is not limited thereto, and the polarization directions of the adjacent piezoelectric films 10 may be the same.

The laminated piezoelectric element in which the long piezoelectric film is folded and laminated as shown in FIG. 1 has the following advantages.

That is, in a case where the cut sheet-like piezoelectric films 10 are laminated in a plurality of layers, it is necessary to connect the first electrode layer 24 and the second electrode layer 26 to a driving power supply for each piezoelectric film. On the contrary, in the configuration in which the long piezoelectric film 10 is folded and laminated, only one sheet of the long piezoelectric film 10 can form the laminate. In addition, in the configuration in which the long piezoelectric film 10 is folded and laminated, only one power supply is required for applying the driving voltage, and the electrodes may be led out from the piezoelectric film 10 at one place.

Furthermore, in the configuration in which the long piezoelectric film 10 is folded and laminated, the polarization directions of the adjacent piezoelectric films are inevitably opposite to each other (see arrows in the piezoelectric layer 20 of FIG. 3). Accordingly, even in a case where the electrode layers of the adjacent piezoelectric films 10 come into contact with each other, there is no risk of a short circuit.

In addition, in the example shown in FIG. 1, the shape of the laminated piezoelectric element 50 (laminated portion) in a plan view is a substantially rectangular shape; but the present invention is not limited thereto, and various shapes such as a square shape, a circular shape, an elliptical shape, a polygonal shape, and an irregular shape can be adopted.

As in the example shown in FIG. 1, in a case where the shape of the laminated piezoelectric element 50 (laminated portion) in a plan view is a substantially rectangular shape, it is preferable to adopt the configuration in which the adhesive region 18 and the gap portion 17 are alternately arranged in the long side direction. That is, it is preferable that the adhesive region 18 and the gap portion 17 are alternately arranged in a direction in which the adhesive region 18 and the gap portion 17 are more largely curved.

### <Adhesive Layer and Pressure-Sensitive Adhesive Layer>

As an adhesive (pressure sensitive adhesive) used for the adhesive layer 19 (adhesive region 18) for bonding the piezoelectric films 10 to each other, various known adhesives can be used as long as the adjacent piezoelectric films 10 can be bonded to each other.

In addition, as an adhesive (pressure sensitive adhesive) used for the bonding layer 104 for attaching the laminated piezoelectric element 50 to the vibration plate 102, various known adhesives can be used as long as the laminated piezoelectric element 50 and the vibration plate 102 can be attached to each other.

The adhesive layer 19 (adhesive region 18) and the bonding layer 104 may be a layer formed of an adhesive which has fluidity in a case of bonding and then is to be a solid, a layer formed of a pressure sensitive adhesive which is a gel-like (rubber-like) soft solid in a case of bonding and the gel-like state does not change thereafter, or a layer formed of a material having characteristics of both the adhesive and the pressure sensitive adhesive.

Here, in the laminated piezoelectric element 50, each laminated piezoelectric film 10 stretches and contracts to bend and vibrate the vibration plate 102, and thus generate a sound. Therefore, in the electroacoustic transducer 100, it is preferable that the stretch and contraction of the laminated piezoelectric element 50 is directly transmitted to the vibration plate 102. In a case where a substance having viscosity, which relieves vibration, is present between the vibration plate 102 and the laminated piezoelectric element 50 and between the piezoelectric films 10, efficiency of transmitting the stretching and contracting energy of the laminated piezoelectric element 50 to the vibration plate 102 is lowered, and driving efficiency of the electroacoustic transducer 100 is also decreased.

In consideration of this point, it is preferable that the adhesive layer 19 for bonding the piezoelectric films to each other and the bonding layer 104 for attaching the vibration plate and the laminated piezoelectric element to each other are adhesive layers formed of an adhesive which is a solid and rigid bonding layer, rather than pressure-sensitive adhesive layers formed of a pressure sensitive adhesive. As a more preferred bonding layer, specifically, a bonding layer consisting of a thermoplastic type adhesive such as a polyester-based adhesive and a styrene-butadiene rubber (SBR)-based adhesive is exemplified.

The adhesion, unlike pressure sensitive adhesion, is useful in a case where a high adhesion temperature is required. In addition, the thermoplastic type adhesive has “comparatively low temperature, short time, and strong adhesion”, which is suitable.

A thickness of the adhesive layer 19 is not limited, and a thickness at which sufficient bonding strength (adhesive force or pressure sensitive adhesive force) can be obtained may be appropriately set depending on the material of the adhesive layer 19.

Here, in the laminated piezoelectric element 50, as the adhesive layer is thinner, the effect of transmitting the stretching and contracting energy (vibration energy) from each piezoelectric film 10 to the vibration plate 102 is higher, and the energy efficiency is higher. In addition, in a case where the adhesive layer is too thick, stiffness is increased, and there is a possibility that the stretch and contraction of the piezoelectric film 10 (laminated piezoelectric element 50) is constrained. On the other hand, in a case where the adhesive layer is too thin, a bonding force is weakened, and there is a risk of peeling between the piezoelectric film 10 and the adhesive layer 19.

In consideration of this point, the thickness of the adhesive layer 19 is preferably 0.1 to 50 μm, more preferably 0.1 to 30 μm, and still more preferably 0.1 to 10 μm in terms of thickness after bonding.

A thickness of the bonding layer 104 is not limited, and a thickness at which sufficient bonding strength (adhesive force or pressure sensitive adhesive force) can be obtained may be appropriately set depending on the material of the bonding layer 104.

Here, in the electroacoustic transducer 100, as the bonding layer is thinner, the effect of transmitting the stretching and contracting energy (vibration energy) of the laminated piezoelectric element 50 to the vibration plate 102 is higher, and the energy efficiency is higher. In addition, in a case where the bonding layer is thick and has high stiffness, there is a possibility that the stretch and contraction of the laminated piezoelectric element 50 may be constrained.

In consideration of this point, it is preferable that the bonding layer is thin. Specifically, the thickness of the bonding layer is preferably 0.1 to 50 μm, more preferably 0.1 to 30 μm, and still more preferably 0.1 to 10 μm in terms of thickness after bonding.

In the electroacoustic transducer 100, the bonding layer 104 is provided as a preferred aspect, and is not an essential constituent element.

Therefore, the electroacoustic transducer 100 may not include the bonding layer 104, and the vibration plate 102 may be fixed to the laminated piezoelectric element 50 using a known compression-bonding unit, fastening unit, fixing unit, or the like. For example, in a case where a shape of the laminated piezoelectric element 50 is a rectangular shape in a plan view, the electroacoustic transducer may be configured by fastening four corners with members such as bolts and nuts, or the electroacoustic transducer may be configured by fastening the four corners and a center portion with members such as bolts and nuts.

However, in such a case, in a case where the driving voltage is applied from the power supply, the laminated piezoelectric element 50 may stretch and contract independently of the vibration plate 102, and in some cases, only the laminated piezoelectric element 50 bends, and the stretch and contraction of the laminated piezoelectric element 50 may not be transmitted to the vibration plate 102. As described above, in a case where the laminated piezoelectric element 50 stretches and contracts independently of the vibration plate 102, the vibration efficiency of the vibration plate 102 due to the laminated piezoelectric element 50 decreases. As a result, the vibration plate 102 may not be sufficiently vibrated.

In consideration of this point, it is preferable that the vibration plate 102 and the laminated piezoelectric element 50 are attached to each other with the bonding layer.

### <Vibration Plate>

As a preferred aspect, the vibration plate 102 has flexibility. In the present invention, the expression of “having flexibility” is synonymous with having flexibility in the general interpretation, and indicates being capable of bending and being flexible, specifically, being capable of bending and stretching without causing breakage and damage.

The vibration plate 102 is not limited as long as the vibration plate preferably has flexibility, and various sheet-like materials (plate-like material and film) can be used.

Examples thereof include resin films made of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), cyclic olefin-based resins, or the like; foamed plastic made of foamed polystyrene, foamed styrene, foamed polyethylene, or the like; veneer boards, cork boards, leathers such as cowhide, various kinds of paperboards such as carbon sheets and Japanese paper, various kinds of corrugated cardboard materials obtained by bonding, to one or both surfaces of a corrugated paperboard, other paperboards; and various kinds of metals such as stainless steel, aluminum, copper, and nickel, and a thin film metal consisting of various kinds of alloys. In addition, the vibration plate 102 may be made of a composite material obtained by bonding a film-like material consisting of these materials.

In addition, various display devices such as an organic electro-luminescence (organic light emitting diode (OLED)) display, a liquid crystal display, a micro light emitting diode (LED) display, and an inorganic electroluminescence display, and projector screens can also be suitably used as the vibration plate 102 as long as they have flexibility.

In the electroacoustic transducer 100, it is preferable that the electrode layer of the laminated piezoelectric element 50 (piezoelectric film 10) and the vibration plate 102 are not electrically connected to each other.

In a case where the electrode layer of the laminated piezoelectric element 50 and the vibration plate 102 are electrically connected to each other, there is a concern that troubles such as a short circuit may occur. Therefore, by adopting the configuration in which the electrode layer of the laminated piezoelectric element 50 and the vibration plate 102 are not electrically connected to each other, the risk of occurrence of failure can be reduced.

### <Piezoelectric Film>

Hereinafter, the piezoelectric film used in the laminated piezoelectric element according to the embodiment of the present invention will be described.

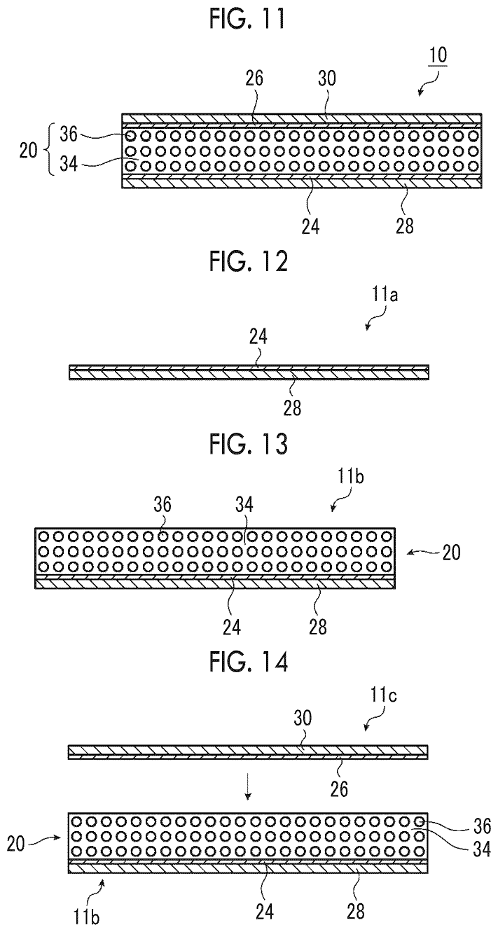

FIG. 11 is an enlarged view of a part of the piezoelectric film 10.

The piezoelectric film 10 shown in FIG. 11 includes a piezoelectric layer 20 which is a sheet-like material having piezoelectric characteristics, a first electrode layer 24 laminated on one surface of the piezoelectric layer 20, a first protective layer 28 laminated on a surface of the first electrode layer 24 opposite to the piezoelectric layer 20, a second electrode layer 26 laminated on the other surface of the piezoelectric layer 20, and a second protective layer 30 laminated on a surface of the second electrode layer 26 opposite to the piezoelectric layer 20. That is, the piezoelectric film 10 has a configuration in which the piezoelectric layer 20 is sandwiched between the electrode layers and the protective layer is laminated on a surface of the electrode layer, which is not in contact with the piezoelectric layer.

In the present invention, various known piezoelectric layers can be used as the piezoelectric layer 20.

In the present invention, as conceptually shown in FIG. 11, the piezoelectric layer 20 is preferably a polymer-based piezoelectric composite material containing piezoelectric particles 36 in a matrix 34 containing a polymer material.

As a material of the matrix 34 (serving as a matrix and a binder) of the polymer-based piezoelectric composite material constituting the piezoelectric layer 20, it is preferable to use a polymer material having viscoelasticity at normal temperature. In the present specification, the “normal temperature” indicates a temperature range of approximately 0° C. to 50° C.

Here, it is preferable that the polymer-based piezoelectric composite material (piezoelectric layer 20) satisfies the following requirements.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

That is, the flexible polymer-based piezoelectric composite material used as an exciter is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

Furthermore, it is preferable that the spring constant can be easily adjusted by lamination in accordance with the stiffness (hardness, stiffness, and spring constant) of the mating material (vibration plate) to be attached. In that regard, as the bonding layer 104 is thinner, the energy efficiency can be increased.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 20), the polymer-based piezoelectric composite material exhibiting a behavior of being rigid with respect to the vibration of 20 Hz to 20 kHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that a polymer material in which the glass transition point at a frequency of 1 Hz is at normal temperature, that is, in a range of 0° C. to 50° C. is used for a matrix of the polymer-based piezoelectric composite material.

As the polymer material having a viscoelasticity at normal temperature, various known materials can be used. It is preferable that a polymer material in which the maximal value of a loss tangent Tan δ at a frequency of 1 Hz according to a dynamic viscoelasticity test at normal temperature, that is, in a range of 0° C. to 50° C. is 0.5 or more is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at normal temperature, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 kHz.

In addition, it is more suitable that a relative permittivity of the polymer material having a viscoelasticity at normal temperature is 10 or more at 25° C. Accordingly, in a case where a voltage is applied to the polymer-based piezoelectric composite material, a higher electric field is applied to the piezoelectric particles in the matrix, and thus a large deformation amount can be expected.

However, in consideration of ensuring favorable moisture resistance and the like, it is suitable that the relative permittivity of the polymer material is 10 or less at 25° C.

Examples of the polymer material having a viscoelasticity at normal temperature and satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, as the polymer material, a material having a cyanoethyl group is preferably used, and cyanoethylated PVA is particularly preferably used.

Among these, as the polymer material having viscoelasticity at normal temperature, it is preferable to use a polymer material having a cyanoethyl group and particularly preferable to use cyanoethylated PVA. That is, in the present invention, as the matrix 34 of the piezoelectric layer 20, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

The matrix 34 using such a polymer material having a viscoelasticity at normal temperature may use a plurality of polymer materials in combination as necessary.

That is, in order to control dielectric properties, mechanical properties, or the like, other dielectric polymer materials may be added to the matrix 34 as necessary, in addition to the viscoelastic material such as cyanoethylated PVA.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the matrix 34 of the piezoelectric layer 20, the number of these dielectric polymer materials is not limited to one, and a plurality of kinds of dielectric polymer materials may be added.

In addition, for the purpose of controlling the glass transition point Tg, a thermoplastic resin such as a vinyl chloride resin, polyethylene, polystyrene, a methacrylic resin, polybutene, and isobutylene, and a thermosetting resin such as a phenol resin, a urea resin, a melamine resin, an alkyd resin, and mica may be added to the matrix 34 in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the matrix 34 of the piezoelectric layer 20, an addition amount of materials to be added, other than the polymer material having viscoelasticity, such as cyanoethylated PVA, is not particularly limited, but is preferably set to 30% by mass or less in terms of the proportion of the materials in the matrix 34.

In this manner, characteristics of the polymer material to be added can be exhibited without impairing the viscoelasticity relaxing mechanism in the matrix 34, so that preferred results such as an increase in permittivity, improvement of heat resistance, and improvement of adhesiveness between the piezoelectric particles 36 and the electrode layer can be obtained.

The piezoelectric layer 20 is a layer consisting of the polymer-based piezoelectric composite material containing the piezoelectric particles 36 in the matrix 34. The piezoelectric particles 36 are dispersed in the matrix 34. It is preferable that the piezoelectric particles 36 are dispersed uniformly (substantially uniform) in the matrix 34.

The piezoelectric particles 36 consist of ceramic particles having a perovskite type or wurtzite type crystal structure.

Examples of the ceramic particles constituting the piezoelectric particles 36 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFe₃).

A particle diameter of the piezoelectric particles 36 is not limited, and may be suitably selected depending on the size of the piezoelectric film 10 and the applications of the laminated piezoelectric element 50. The particle diameter of the piezoelectric particles 36 is preferably 1 to 10 μm.

By setting the particle diameter of the piezoelectric particles 36 to be within the above-described range, preferred results in terms of achieving both excellent piezoelectric characteristics and flexibility of the piezoelectric film 10 can be obtained.

The piezoelectric particles 36 in the piezoelectric layer 20 may be uniformly and regularly dispersed in the matrix 34, or may be uniformly dispersed in the matrix 34 even in a case where the piezoelectric particles 36 are irregularly dispersed in the matrix 34.

In the piezoelectric film 10, a ratio between an amount of the matrix 34 and an amount of the piezoelectric particles 36 in the piezoelectric layer 20 is not limited, and may be appropriately set according to the size and the thickness of the piezoelectric film 10 in the plane direction, the applications of the laminated piezoelectric element 50, the characteristics required for the laminated piezoelectric element 50, and the like.

A volume fraction of the piezoelectric particles 36 in the piezoelectric layer 20 is preferably 30% to 80%, more preferably 50% or more, and still more preferably 50% to 80%.

By setting the ratio between the amount of the matrix 34 and the amount of the piezoelectric particles 36 to be within the above-described range, preferred results in terms of achieving both of excellent piezoelectric characteristics and flexibility can be obtained.

In the piezoelectric film 10, a thickness of the piezoelectric layer 20 is not particularly limited and may be appropriately set according to the applications of the laminated piezoelectric element 50, the number of lamination of the piezoelectric film in the laminated piezoelectric element 50, the characteristics required for the piezoelectric film 10, and the like.

It is advantageous that the thickness of the piezoelectric layer 20 increases large in terms of stiffness such as the strength of stiffness of a so-called sheet-like material, but the voltage (potential difference) required to stretch and contract the piezoelectric film 10 increases by the same amount.

The thickness of the piezoelectric layer 20 is preferably 10 to 300 μm, more preferably 20 to 200 μm, and still more preferably 30 to 150 μm.

By setting the thickness of the piezoelectric layer 20 to be within the above-described ranges, preferred results in terms of achieving both ensuring of the stiffness and moderate elasticity can be obtained.

In addition, it is preferable that the piezoelectric layer 20 is subjected to a polarization treatment (poling) in the thickness direction. In a case where a voltage is applied to the electrode layers (electrode pair) which sandwich the piezoelectric layer 20, the piezoelectric particles 36 in the piezoelectric layer 20 stretch and contract in the polarization direction according to the applied voltage. As a result, the piezoelectric film 10 (piezoelectric layer 20) contracts in the thickness direction. At the same time, the piezoelectric film 10 stretches and contracts in the plane direction due to the Poisson's ratio. In this manner, the piezoelectric film 10 can exhibit piezoelectric characteristics.

In the present invention, the piezoelectric layer 20 is not limited to the polymer-based piezoelectric composite material containing the piezoelectric particles 36 in the matrix 34 consisting of a polymer material having viscoelasticity at normal temperature, such as cyanoethylated PVA, as described above.

That is, in the piezoelectric film 10 according to the present invention, various known piezoelectric layers can be used as the piezoelectric layer.

As an example, a polymer-based piezoelectric composite material containing the same piezoelectric particles 36 in a matrix containing a dielectric polymer material such as polyvinylidene fluoride, a vinylidene fluoride-tetrafluoroethylene copolymer, and a vinylidene fluoride-trifluoroethylene copolymer described above, a piezoelectric layer consisting of polyvinylidene fluoride, a piezoelectric layer consisting of a fluororesin other than polyvinylidene fluoride, a piezoelectric layer obtained by laminating a film consisting of poly-L lactic acid and a film consisting of poly-D lactic acid, and the like are also available.

However, as described above, from the viewpoint that the polymer-based piezoelectric composite material can behave hard for vibrations at 20 Hz to 20 kHz and behave softly for slow vibrations at less than or equal to a few Hz, has excellent acoustic characteristics, and has excellent flexibility, a polymer-based piezoelectric composite material containing the piezoelectric particles 36 in the matrix 34 consisting of a polymer material having viscoelasticity at normal temperature, such as cyanoethylated PVA described above, is suitably used.

As shown in FIG. 11, the piezoelectric film 10 has a configuration in which the first electrode layer 24 is provided on one surface of the piezoelectric layer 20, the first protective layer 28 is provided thereon, the second electrode layer 26 is provided on the other surface of the piezoelectric layer 20, and the second protective layer 30 is provided thereon. Here, the first electrode layer 24 and the second electrode layer 26 form an electrode pair.

That is, the piezoelectric film 10 has a configuration in which both surfaces of the piezoelectric layer 20 are sandwiched between the electrode pair, that is, the first electrode layer 24 and the second electrode layer 26, and this laminate is sandwiched between the first protective layer 28 and the second protective layer 30.

In this way, in the piezoelectric film 10, a region sandwiched between the first electrode layer 24 and the second electrode layer 26 stretches and contracts according to an applied voltage.

The first electrode layer 24 and the first protective layer 28, and the second electrode layer 26 and the second protective layer 30 are used for describing the piezoelectric film 10 for convenience. Therefore, the terms “first” and “second” in the present invention have no technical meanings and are irrelevant to the actual usage state.

The piezoelectric film 10 in the present invention may include, in addition to those layers, for example, a bonding layer for bonding the electrode layer and the piezoelectric layer 20 to each other, and a bonding layer for bonding the electrode layer and the protective layer to each other.

The bonding agent may be an adhesive or a pressure sensitive adhesive. In addition, the same material as the polymer material obtained by removing the piezoelectric particles 36 from the piezoelectric layer 20, that is, the matrix 34 can also be suitably used as the bonding agent. The bonding layer may be provided on both the first electrode layer 24 side and the second electrode layer 26 side, or may be provided only on one of the first electrode layer 24 side or the second electrode layer 26 side.

The first protective layer 28 and the second protective layer 30 in the piezoelectric film 10 have a function of coating the first electrode layer 24 and the second electrode layer 26 and imparting moderate stiffness and mechanical strength to the piezoelectric layer 20. That is, the piezoelectric layer 20 consisting of the matrix 34 and the piezoelectric particles 36 in the piezoelectric film 10 exhibits extremely excellent flexibility under bending deformation at a slow vibration, but may have insufficient stiffness or mechanical strength depending on the applications. As a compensation for this, the piezoelectric film 10 is provided with the first protective layer 28 and the second protective layer 30.

The first protective layer 28 and the second protective layer 30 have the same configuration despite of different disposition positions. Accordingly, in the following description, in a case where it is not necessary to distinguish the first protective layer 28 from the second protective layer 30, both members are collectively referred to as a protective layer.

The protective layer is not limited, and various sheet-like materials can be used as the protective layer, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfide (PPS), polymethylmethacrylate (PMMA), polyetherimide (PEI), polyimide (PI), polyethylene naphthalate (PEN), triacetyl cellulose (TAC), a cyclic olefin-based resin, and the like is suitably used.

A thickness of the protective layer is not limited. In addition, the thicknesses of the first protective layer 28 and the second protective layer 30 are basically the same as each other, but may be different from each other.

Here, in a case where the stiffness of the protective layer is extremely high, not only is the stretch and contraction of the piezoelectric layer 20 constrained, but also the flexibility is impaired. Therefore, it is advantageous that the thickness of the protective layer decrease except for a case where the mechanical strength or excellent handleability as a sheet-like material is required.

In a case where the thickness of the protective layer in the piezoelectric film 10 is two times or less the thickness of the piezoelectric layer 20, preferred results in terms of achieving both ensuring of the stiffness and moderate elasticity can be obtained.

For example, in a case where the thickness of the piezoelectric layer 20 is 50 μm and the protective layer consists of PET, the thickness of the protective layer is preferably 100 μm or less, more preferably 50 μm or less, and still more preferably 25 μm or less.

In the piezoelectric film 10, the first electrode layer 24 is formed between the piezoelectric layer 20 and the first protective layer 28, and the second electrode layer 26 is formed between the piezoelectric layer 20 and the second protective layer 30. The first electrode layer 24 and the second electrode layer 26 are provided to apply a voltage to the piezoelectric layer 20 (piezoelectric film 10).

The first electrode layer 24 and the second electrode layer 26 are basically the same, except that the positions are different. Accordingly, in the following description, in a case where it is not necessary to distinguish the first electrode layer 24 and the second electrode layer 26, both members are collectively referred to as an electrode layer.

In the present invention, a forming material of the electrode layer is not limited, and various conductors can be used as the forming material. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Specific examples thereof also include conductive polymers such as polyethylene dioxythiophene-polystyrene sulfonic acid (PEDOT/PPS).

Among these, copper, aluminum, gold, silver, platinum, or indium tin oxide is suitably exemplified as the electrode layer. Among these, from the viewpoint of the conductivity, the cost, and the flexibility, copper is more preferable.

In addition, a method of forming the electrode layer is not limited, and various known methods, for example, a vapor-phase deposition method (a vacuum film forming method) such as vacuum vapor deposition or sputtering, a film forming method using plating, and a method of bonding a foil formed of the materials described above can be used.

Among these, particularly from the viewpoint of ensuring the flexibility of the piezoelectric film 10, a thin film made of copper, aluminum, or the like formed by vacuum vapor deposition is suitably used as the electrode layer. Among these, a thin film made of copper, which is formed by vacuum vapor deposition, is particularly suitably used.

A thickness of the electrode layer is not limited. In addition, the thicknesses of the first electrode layer 24 and the second electrode layer 26 are basically the same as each other, but may be different from each other.

Here, similarly to the above-described protective layer, in a case where the stiffness of the electrode layer is extremely high, not only is the stretch and contraction of the piezoelectric layer 20 constrained, but also the flexibility is impaired. Therefore, it is advantageous that the thickness of the electrode layer is reduced in a case where an electric resistance is not excessively high.

In the piezoelectric film 10, it is suitable that a product of the thickness of the electrode layer and the Young's modulus thereof is less than a product of the thickness of the protective layer and the Young's modulus thereof because the flexibility is not considerably impaired.

For example, in a case of a combination consisting of the protective layer formed of PET (Young's modulus: approximately 6.2 GPa) and the electrode layer formed of copper (Young's modulus: approximately 130 GPa), assuming that the thickness of the protective layer is 25 μm, the thickness of the electrode layer is preferably 1.2 μm or less, more preferably 0.3 μm or less, and still more preferably 0.1 μm or less.

As described above, the piezoelectric film 10 has a configuration in which the piezoelectric layer 20 obtained by dispersing the piezoelectric particles 36 in the matrix 34 containing the polymer material is sandwiched between the first electrode layer 24 and the second electrode layer 26, and this laminate is sandwiched between the first protective layer 28 and the second protective layer 30.

In such a piezoelectric film 10, it is preferable that the maximal value of the loss tangent (Tan δ) at a frequency of 1 Hz according to the dynamic viscoelasticity measurement is present at normal temperature, and it is more preferable that the maximal value at which the loss tangent is 0.1 or more is present at normal temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 10, it is preferable that the storage elastic modulus (E′) at a frequency of 1 Hz according to the dynamic viscoelasticity measurement is 10 to 30 GPa at 0° C. and 1 to 10 GPa at 50° C. The same applies to the conditions for the piezoelectric layer 20.

In such a manner, the piezoelectric film 10 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In addition, in the piezoelectric film 10, it is preferable that a product of the thickness and the storage elastic modulus (E′) at a frequency of 1 Hz according to the dynamic viscoelasticity measurement is 1.0×10⁵ to 2.0×10⁶ N/m at 0° C. and 1.0×10⁵ to 1.0×10⁶ N/m at 50° C. The same applies to the conditions for the piezoelectric layer 20.

In this manner, the piezoelectric film 10 may have moderate stiffness and mechanical strength within a range not impairing the flexibility and the acoustic characteristics.

Furthermore, in the piezoelectric film 10, it is preferable that the loss tangent (Tan δ) at a frequency of 1 kHz at 25° C. is 0.05 or more in a master curve obtained from the dynamic viscoelasticity measurement. The same applies to the conditions for the piezoelectric layer 20.

In this manner, the frequency characteristics of the speaker including the piezoelectric film 10 are smooth, so that an amount of change in acoustic quality in a case where the lowest resonance frequency f₀ is changed according to a change in curvature of the speaker can be decreased.

In addition, in the present invention, the storage elastic modulus (Young's modulus) and the loss tangent of the piezoelectric film 10, the piezoelectric layer 20, and the like may be measured by a known method. As an example, the measurement may be performed using a dynamic viscoelasticity measuring device DMS6100 (manufactured by SII Nanotechnology Inc.).

Examples of measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

In the laminated piezoelectric element 50, the first electrode layer 24 and the second electrode layer 26 of the piezoelectric film 10 are connected to a power supply (external power supply) which applies a driving voltage, that is, supplies a driving power for stretching and contracting the piezoelectric film 10.

The power supply is not limited, and may be a direct-current power supply or an alternating-current power supply. In addition, as the driving voltage, a driving voltage capable of suitably driving the piezoelectric films 10 may be suitably set in accordance with the thickness, forming material, and the like of the piezoelectric layer 20 in the piezoelectric film 10.

As described above, the piezoelectric film 10 includes the piezoelectric layer 20 consisting of the polymer-based piezoelectric composite material containing the piezoelectric particles 36 in the matrix 34 containing the polymer material, and the electrode layers (the first electrode layer 24 and the second electrode layer 26) provided on both surfaces of the piezoelectric layer 20. In addition, the piezoelectric film 10 includes the protective layers (the first protective layer 28 and the second protective layer 30) provided on the respective electrode layers.

In a case where a voltage is applied to the first electrode layer 24 and the second electrode layer 26 of the piezoelectric film 10 including such a piezoelectric layer 20, the piezoelectric particles 36 stretch and contract in the polarization direction according to the applied voltage. As a result, the piezoelectric film 10 (piezoelectric layer 20) contracts in the thickness direction. At the same time, the piezoelectric film 10 stretches and contracts in the in-plane direction due to the Poisson's ratio. A degree of stretch and contraction is approximately 0.01% to 0.1%.

As described above, the thickness of the piezoelectric layer 20 is preferably approximately 10 to 300 μm. Accordingly, the degree of stretch and contraction in the thickness direction is as extremely small as approximately 0.3 μm at the maximum.

On the contrary, the piezoelectric film 10, that is, the piezoelectric layer 20, has a size much larger than the thickness in a plane direction. Therefore, for example, in a case where a length of the laminated portion of the laminated piezoelectric element is 20 cm, the piezoelectric film 10 stretches and contracts in the plane direction by a maximum of approximately 0.2 mm by the application of the voltage.

The vibration plate 102 is attached to the piezoelectric film 10 (laminated piezoelectric element 50) with a bonding layer. Accordingly, the stretch and contraction of the piezoelectric film 10 causes the vibration plate 102 to bend, and as a result, the vibration plate 102 vibrates in the thickness direction.

The vibration plate 102 generates a sound using the vibration in the thickness direction. That is, the vibration plate 102 vibrates according to the magnitude of the voltage (driving voltage) applied to the piezoelectric film 10, and generates a sound according to the driving voltage applied to the piezoelectric film 10.

In addition, the sound pressure level can be improved by adjusting the mass of the piezoelectric film 10 (laminated piezoelectric element 50) in accordance with a spring constant of the vibration plate 102. In a case where the mass of the laminated piezoelectric element 50 is large, the vibration plate 102 is bent, and thus there is a possibility that the vibration of the vibration plate 102 during driving is suppressed. On the other hand, in a case where the mass of the laminated piezoelectric element 50 is small, the resonance frequency is high, and the vibration of the vibration plate 102 at a low frequency may be suppressed. In consideration of these points, it is preferable that the mass of the laminated piezoelectric element 50 is appropriately adjusted according to the spring constant of the vibration plate 102.

### <Method for Manufacturing Piezoelectric Film>

Next, an example of a method for manufacturing the piezoelectric film 10 will be described with reference to FIGS. 12 to 14.

First, as shown in FIG. 12, a sheet-like material 11a in which the first electrode layer 24 has been formed on a surface of the first protective layer 28 is prepared. Furthermore, as conceptually shown in FIG. 14, a sheet-like material 11c in which the second electrode layer 26 has been formed on a surface of the second protective layer 30 is prepared.

The sheet-like material 11a may be produced by forming a copper thin film or the like as the first electrode layer 24 on the surface of the first protective layer 28 using vacuum vapor deposition, sputtering, plating, or the like. Similarly, the sheet-like material 11c may be produced by forming a copper thin film or the like as the second electrode layer 26 on the surface of the second protective layer 30 using vacuum vapor deposition, sputtering, plating, or the like.

Alternatively, a commercially available sheet-like material in which a copper thin film or the like is formed on a protective layer may be used as the sheet-like material 11a and/or the sheet-like material 11c.

The sheet-like material 11a and the sheet-like material 11c may be exactly the same or different from each other.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

Next, as shown in FIG. 13, the first electrode layer 24 of the sheet-like material 11a is coated with a coating material (coating composition) forming the piezoelectric layer 20, and the coating material is cured to form the piezoelectric layer 20. In this manner, a piezoelectric laminate 11b in which the sheet-like material 11a and the piezoelectric layer 20 are laminated is produced.

The piezoelectric layer 20 can be formed by various methods depending on the forming material of the piezoelectric layer 20.

As an example, first, the coating material is prepared by dissolving the above-described polymer material such as cyanoethylated PVA in an organic solvent, adding the piezoelectric particles 36 such as PZT particles thereto, and stirring the solution.

The organic solvent is not limited, and various organic solvents such as dimethylformamide (DMF), methyl ethyl ketone (MEK), and cyclohexanone can be used.

In a case where the sheet-like material 11a is prepared and the coating material is prepared, the coating material is cast (applied) onto the sheet-like material 11a, and the organic solvent is evaporated and dried. In this manner, as shown in FIG. 13, the piezoelectric laminate 11b in which the first electrode layer 24 is provided on the first protective layer 28 and the piezoelectric layer 20 is laminated on the first electrode layer 24 is produced.

A casting method of the coating material is not limited, and all known methods (coating devices) such as a bar coater, a slide coater, and a doctor knife can be used.

Alternatively, in a case where the polymer material is a material that can be heated and melted, the piezoelectric laminate 11b as shown in FIG. 13 may be produced by heating and melting the polymer material to produce a melt obtained by adding the piezoelectric particles 36 to the melted material, extruding the melt on the sheet-like material 11a as shown in FIG. 12 in a sheet shape by carrying out extrusion molding or the like, and cooling the laminate.

As described above, in the piezoelectric layer 20 a polymer piezoelectric material such as PVDF may be added to the matrix 34, in addition to the polymer material having viscoelasticity at normal temperature.

In a case where the polymer piezoelectric material is added to the matrix 34, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 20, a calender treatment may be performed as necessary. The calender treatment may be performed once or a plurality of times.

As is well known, the calender treatment is a treatment in which the surface to be treated is pressed while being heated by a heating press, a heating roller, or the like to flatten the surface.

Next, the piezoelectric layer 20 of the piezoelectric laminate 11b is subjected to a polarization treatment (poling). The polarization treatment of the piezoelectric layer 20 may be performed before the calender treatment, but it is preferable that the polarization treatment is performed after the calender treatment.

A method of performing the polarization treatment on the piezoelectric layer 20 is not limited, and a known method can be used. For example, electric field poling treatment in which DC electric field is directly applied to a target to be subjected to the polarization treatment, a corona poling treatment, or the like is exemplified. In a case of performing the electric field poling treatment, the electric field poling treatment may be performed using the first electrode layer 24 and the second electrode layer 26 by forming the second electrode layer 26 before the polarization treatment.

In addition, in the piezoelectric film 10 according to the present invention, the polarization treatment is performed in the thickness direction instead of the plane direction of the piezoelectric layer 20.

Next, as shown in FIG. 14, the sheet-like material 11c which has been prepared in advance is laminated on the piezoelectric layer 20 side of the piezoelectric laminate 11b which has been subjected to the polarization treatment, such that the second electrode layer 26 faces the piezoelectric layer 20.

Furthermore, the piezoelectric film 10 as shown in FIG. 11 is produced by subjecting the laminate to a thermal compression bonding using a heating press device, a heating roller, or the like such that the first protective layer 28 and the second protective layer 30 are sandwiched, and bonding the piezoelectric laminate 11b to the sheet-like material 11c.

Alternatively, the piezoelectric film 10 may be produced by bonding and preferably further compression-bonding the piezoelectric laminate 11b and the sheet-like material 11c to each other using an adhesive. As the adhesive in this case, the same material as the matrix of the piezoelectric layer 20 can be used.

The piezoelectric film 10 may be produced using the cut sheet-like material 11a and the cut sheet-like material 11c, or may be produced by roll-to-roll.

The produced piezoelectric film may be cut into a desired shape according to various applications.

The piezoelectric film 10 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

### <Method for Manufacturing Laminated Piezoelectric Element>

Next, a method for manufacturing the laminated piezoelectric element by folding the long piezoelectric film shown in FIG. 1 a plurality of times will be described.

First, a long piezoelectric film is prepared, and an adhesive (pressure sensitive adhesive) is applied onto the entire region of a first laminated portion when folded back, and cured. Alternatively, an adhesive sheet is attached thereto.

Next, a part of the adhesive (pressure sensitive adhesive) or the adhesive sheet is removed according to a desired arrangement pattern to form the gap portion. A method of removing the adhesive or the adhesive sheet is not particularly limited. Examples thereof include a method of irradiating a position serving as the gap portion with laser light (carbon dioxide laser or the like) to remove the adhesive; and a method of cutting the adhesive or the adhesive sheet in a depth direction by press working (for example, in a case where the thickness of the adhesive or the adhesive sheet is 15 μm, the adhesive or the adhesive sheet is cut to 13 to 14.5 μm in the thickness direction), and then peeling off the adhesive layer or the adhesive sheet at the portion. As a result, for example, the adhesive layer 19 having the adhesive region 18 and the gap portion 17 as shown in FIGS. 4, and 7 to 9 is formed.

Next, the piezoelectric film is folded once, and a region of the piezoelectric film as the first layer and a region of the piezoelectric film as a second layer are bonded to each other with the adhesive layer.

Next, an adhesive (pressure sensitive adhesive) is applied onto the entire region of the second laminated portion in the folded piezoelectric film, and cured. Alternatively, an adhesive sheet is attached thereto.

Thereafter, in the same manner as described above, a part of the adhesive (pressure sensitive adhesive) or the adhesive sheet is removed according to a desired arrangement pattern to form the gap portion, and then the piezoelectric film is folded once to bond a region of the piezoelectric film as the second layer and a region of the piezoelectric film as the third layer to each other with the adhesive layer.

In this manner, by repeating the formation of the adhesive layer and the folding-back of the piezoelectric film, the laminated piezoelectric element formed by folding the long piezoelectric film a plurality of times can be produced.

Hereinbefore, the laminated piezoelectric element and electroacoustic transducer according to the embodiment of the present invention have been described in detail, but the present invention is not limited to the above-described examples, and various improvements or modifications may be made within a range not departing from the scope of the present invention.

### EXAMPLES

Hereinafter, the present invention will be described in more detail with reference to specific examples of the present invention. The present invention is not limited to the examples, and the materials, the used amounts, the proportions, the treatment contents, the treatment procedures, and the like shown in the following examples can be appropriately changed within a range not departing from the scope of the present invention.

### Comparative Example 1

### <Production of Piezoelectric Film>

A piezoelectric film was produced by the method shown in FIGS. 12 to 14 described above.

First, cyanoethylated PVA (CR-V manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass Particles obtained by sintering commercially available PZT raw material powder at 1000° C. to 1200° C. and then crushing and classifying the sintered powder to have an average particle diameter of 2 μm were used as the PZT particles.

On the other hand, a sheet-like material obtained by performing vacuum vapor deposition on a copper thin film having a thickness of 0.1 μm was prepared on a PET film having a thickness of 4 μm. That is, in the present example, the first electrode layer and the second electrode layer were copper-deposited thin films having a thickness of 0.3 μm, and the first protective layer and the second protective layer were PET films having a thickness of 4 μm.

The first electrode layer (copper-deposited thin film) of the sheet-like material was coated with the coating material for forming a piezoelectric layer, which was prepared in advance, using a slide coater. The coating material was applied so that a film thickness of the coating film after drying was 50 μm.

Next, the material obtained by coating the sheet-like material with the coating material was heated and dried on a hot plate at 120° C. to evaporate DMF. In this manner, a piezoelectric laminate in which the first electrode layer made of copper was provided on the first protective layer made of PET and the piezoelectric layer (polymer-based piezoelectric composite material layer) having a thickness of 91.8 μm was formed thereon was produced.

The produced piezoelectric layer was subjected to a polarization treatment in the thickness direction.

A sheet-like material obtained by vapor-depositing a copper thin film on the PET film was laminated on the piezoelectric laminate subjected to the polarization treatment such that the second electrode layer (copper thin film side) faced the piezoelectric layer.

Next, the laminate of the piezoelectric laminate and the sheet-like material was subjected to thermal compression bonding at a temperature of 120° C. using a laminator device to adhere the piezoelectric layer and the second electrode layer by bonding, thereby producing a piezoelectric film as shown in FIG. 11. A thickness of the piezoelectric film was 100 μm.

### <Production of Laminated Piezoelectric Element>

The piezoelectric film was cut into a rectangular shape having a planar shape of 140 mm×150 mm. The cut piezoelectric film was folded three times in a direction of a side of 140 mm to laminate four layers of the piezoelectric film, thereby producing a piezoelectric element. A planar shape of the laminated portion was 30 mm×150 mm.

The layers of the piezoelectric film laminated were bonded to each other with an adhesive layer (acrylic pressure sensitive adhesive). A thickness of the adhesive layer was 5 m. In addition, a gap portion was provided in the adhesive layer. The gap portion was formed with a 30 mm×150 mm adhesive layer in a line shape having a width of 100 μm, at intervals of 100 μm in the 150 mm direction (see FIG. 4).

In addition, an electrode lead-out portion was formed in a region protruding from the laminated portion.

By a cross-sectional observation using the SEM described above, a ratio (hereinafter, also referred to as a thickness ratio) d₂/d₁ of an average value d₁ of thicknesses of the piezoelectric films to an average value d₂ of thicknesses of the adhesive layers, and a ratio (hereinafter, also referred to as an area ratio) of the total area of the gap portions to the total area of the adhesive layers in the produced laminated piezoelectric element of Comparative Example 1 were obtained.

The thickness ratio d₂/d₁ of the produced laminated piezoelectric element of Comparative Example 1 was 0.05. In addition, the area ratio was 20%.

### Examples 1 and 2

A laminated piezoelectric element was produced in the same manner as in Comparative Example 1, except that the thicknesses of the adhesive layer were changed to 15 m and 30 μm, respectively.

The thickness ratio d₂/d₁ of the produced laminated piezoelectric element of Example 1 was 0.15. In addition, the area ratio was 20%.

The thickness ratio d₂/d₁ of the produced laminated piezoelectric element of Example 2 was 0.30. In addition, the area ratio was 20%.

### Comparative Example 2

A laminated piezoelectric element was produced in the same manner as in Comparative Example 1, except that the thickness of the piezoelectric layer was 41.8 μm, the thickness of the piezoelectric film was 50 μm, the thickness of the adhesive layer was 15 μm, and the gap portion was not provided.

The thickness ratio d₂/d₁ of the produced laminated piezoelectric element of Comparative Example 2 was 0.30. In addition, the area ratio was 0%.

### Comparative Example 3

A laminated piezoelectric element was produced in the same manner as in Comparative Example 2, except that the gap portion was provided in the adhesive layer.

The gap portion was formed with a 30 mm×150 mm adhesive layer in a line shape having a width of 100 μm, at intervals of 100 μm in the 150 mm direction (see FIG. 4).

The thickness ratio d₂/d₁ of the produced laminated piezoelectric element of Comparative Example 3 was 0.30. In addition, the area ratio was 50%.

### Examples 3 to 7

A laminated piezoelectric element was produced in the same manner as in Comparative Example 3, except that the width and the interval of the gap portions were changed such that the area ratios were 20%, 1%, 5%, 35%, and 40%, respectively.

The thickness ratios d₂/d₁ of the produced laminated piezoelectric elements of Examples 3 to 7 were all 0.30.

### Examples 8 to 10

A laminated piezoelectric element was produced in the same manner as in Example 3, except that the thickness of the adhesive layer was 5 μm, 30 μm, and 50 μm, respectively.

The thickness ratios d₂/d₁ of the produced laminated piezoelectric elements of Examples 8 to 10 were 0.10, 0.60, and 1.00, respectively.

### Comparative Example 4

A laminated piezoelectric element was produced in the same manner as in Comparative Example 1, except that the thickness of the piezoelectric layer was 5.9 μm, the thickness of the protective layer was 2 μm, the thickness of the electrode layer was 0.05 μm, the thickness of the piezoelectric film was 10 μm, and the thickness of the adhesive layer was 15 μm.

The thickness ratio d₂/d₁ of the produced laminated piezoelectric element of Comparative Example 4 was 1.50. In addition, the area ratio was 20%.

### Example 11

A laminated piezoelectric element was produced in the same manner as in Comparative Example 4, except that the thickness of the adhesive layer was 5 μm.

### [Evaluation]

The produced laminated piezoelectric elements of Examples and Comparative Examples were attached to a vibration plate to produce electroacoustic transducers. As the vibration plate, a plate-shaped member having a size of 500 mm×450 mm, a thickness of 0.8 mm, and a material of aluminum (A5052) was used. A lateral direction of the vibration plate and a longitudinal direction of the laminated piezoelectric element were aligned, and the laminated piezoelectric element was bonded to the center of the laminated portion, aligned with the center of the vibration plate. An acrylic pressure sensitive adhesive was used as the bonding layer for attaching the laminated piezoelectric element to the vibration plate.

One end of the vibration plate in the longitudinal direction was supported, a Sine sweep signal of a frequency of 100 Hz to 5 kHz and an applied voltage of 50 Vrms was input to the laminated piezoelectric element, and the sound pressure was measured with a microphone placed at a distance of 1 μm from the center of the vibration plate. An average value of the sound pressure in a frequency range of 100 Hz to 5 kHz was calculated. The average value of the sound pressure was obtained by extracting the maximal value in the frequency range of 100 Hz to 5 kHz and calculating an average value thereof.

The sound pressure was measured by measuring the initial sound pressure and the sound pressure after continuous driving for 72 hours, and a difference in sound pressure was obtained.

The results are shown in Table 1.

TABLE 1

| | | | | | | Evaluation | | |
|---|---|---|---|---|---|---|---|---|
| | Piezoelectric | Adhesive layer | | | | Initial | Sound pressure | |
| | film | Thickness | Presence or | Area | | sound | after continuous | Difference in |
| | Thickness d₁ | d₂ | absence of gap | ratio | Thickness | pressure | driving | sound pressure |
| | μm | μm | portion | % | ratio | dB | dB | dB |
| Comparative | 100 | 5 | Presence | 20 | 0.05 | 84.7 | 83.2 | 1.5 |
| Example 1 | | | | | | | | |
| Example 1 | 100 | 15 | Presence | 20 | 0.15 | 88.3 | 86.8 | 1.5 |
| Example 2 | 100 | 30 | Presence | 20 | 0.30 | 88.3 | 86.8 | 1.5 |
| Comparative | 50 | 15 | Absence | 0 | 0.30 | 88.8 | 83.8 | 5.0 |
| Example 2 | | | | | | | | |
| Comparative | 50 | 15 | Presence | 50 | 0.30 | 83.0 | 82.5 | 0.5 |
| Example 3 | | | | | | | | |
| Example 3 | 50 | 15 | Presence | 20 | 0.30 | 88.6 | 87.1 | 1.5 |
| Example 4 | 50 | 15 | Presence | 1 | 0.30 | 89.2 | 86.0 | 3.2 |
| Example 5 | 50 | 15 | Presence | 5 | 0.30 | 88.9 | 86.7 | 2.2 |
| Example 6 | 50 | 15 | Presence | 35 | 0.30 | 87.5 | 86.5 | 1.0 |
| Example 7 | 50 | 15 | Presence | 40 | 0.30 | 85.2 | 84.0 | 1.2 |
| Example 8 | 50 | 5 | Presence | 20 | 0.10 | 87.1 | 85.5 | 1.6 |
| Example 9 | 50 | 30 | Presence | 20 | 0.60 | 87.1 | 85.7 | 1.4 |
| Example 10 | 50 | 50 | Presence | 20 | 1.00 | 85.5 | 84.1 | 1.4 |
| Comparative | 10 | 15 | Presence | 20 | 1.50 | 83.2 | 81.7 | 1.5 |
| Example 4 | | | | | | | | |
| Example 11 | 10 | 5 | Presence | 20 | 0.50 | 87.7 | 86.2 | 1.5 |

From Table 1, it was found that the sound pressure after continuous driving in Examples of the present invention was higher than that in Comparative Examples. This is because the decrease in sound pressure over time due to long-term use could be suppressed, and the initial sound pressure was high.

In addition, from the comparison of Examples 3 to 7, it was that the ratio of the total area of the gap portions to the total area of the adhesive layers was preferably 5% to 35%.

In addition, from the comparison of Examples 3 and 8 to 10, it was found that the ratio d₂/d₁ of the thickness of the piezoelectric film to the thickness of the adhesive layer was preferably 0.1 to 0.6.

From the above, the effects of the present invention are clear.

The laminated piezoelectric element according to the embodiment of the present invention is suitably used as the following, for example: as various sensors such as a sound wave sensor, an ultrasonic wave sensor, a pressure sensor, a tactile sensor, a strain sensor, and a vibration sensor (which are useful particularly for an infrastructure examination such as crack detection and a manufacturing site inspection such as foreign matter contamination detection); acoustic devices such as microphones, pickups, speakers, and exciters (as specific applications, noise cancellers (used for cars, trains, airplanes, robots, and the like), artificial voice bands, buzzers to prevent pests and beasts from invading, furniture, wallpaper, photo, helmet, goggles, headrest, signage, robot, and the like are exemplified); haptics used for application to automobiles, smartphones, smart watches, games, and the like; ultrasonic transducers such as ultrasound probe and hydrophones; actuators used for prevention of attachment of water droplets, transportation, agitation, dispersion, polishing, and the like; damping materials (dampers) used for containers, vehicles, buildings, sports equipment such as skis and rackets; and vibration power generator used for application to roads, floors, mattresses, chairs, shoes, tires, wheels, computer keyboards, and the like.

### EXPLANATION OF REFERENCES

10: piezoelectric film
11a, 11c: sheet-like material
11b: piezoelectric laminate
17: gap portion
18: adhesive region
19, 19b to 19d: adhesive layer
20: piezoelectric layer
24: first electrode layer
26: second electrode layer
28: first protective layer
30: second protective layer
34: matrix
36: piezoelectric particle
40, 42: conductive wire
50: laminated piezoelectric element
100: electroacoustic transducer
102: vibration plate
104: bonding layer

What is claimed is:

1. A laminated piezoelectric element in which a plurality of piezoelectric films are laminated with adhesive layers interposed between the plurality of piezoelectric films,
wherein the adhesive layer has an adhesive region and a gap portion in an in-plane direction of a main surface of the piezoelectric films,
in a case where a cross section of the piezoelectric films of the laminated piezoelectric element in a lamination direction is observed with a scanning electron microscope in each of one in-plane direction of the main surface of the piezoelectric films, a direction orthogonal to the one direction, a direction inclined by 45° with respect to the one direction, and a direction inclined by 135° with respect to the one direction to acquire ten continuous visual fields, and an average value of thicknesses of the piezoelectric films observed in each visual field is denoted by d₁ and an average value of thicknesses of the adhesive layers observed in each visual field is denoted by d₂, a ratio d₂/d₁ is 0.15 or more and 1.0 or less, and
a ratio of a total area of the gap portions to a total area of the adhesive layers observed in each visual field is 1% or more and 40% or less.

2. The laminated piezoelectric element according to claim 1,
wherein the piezoelectric film includes a piezoelectric layer consisting of a polymer-based piezoelectric composite material containing piezoelectric particles in a matrix containing a polymer material, and electrode layers provided on both surfaces of the piezoelectric layer.

3. The laminated piezoelectric element according to claim 1,
wherein the piezoelectric film is laminated in a plurality of layers by folding the piezoelectric film one or more times.

4. An electroacoustic transducer obtained by attaching the laminated piezoelectric element according to claim 1 to a vibration plate.

5. An electroacoustic transducer obtained by attaching the laminated piezoelectric element according to claim 2 to a vibration plate.

6. An electroacoustic transducer obtained by attaching the laminated piezoelectric element according to claim 3 to a vibration plate.
